(19) United States
(12) Patent Application Publication
(10) Pub. No.: US 2006/0011967 A1
(43) Pub. Date: Jan. 19, 2006

(54) Split gate memory structure and manufacturing method thereof

(75) Inventor: Fuja Shone, Hsinchu (TW)

Correspondence Address: OLIFF & BERRIDGE, PLC, P.O. BOX 19928, ALEXANDRIA, VA, 22320, US

(73) Assignee: SKYMEDI CORPORATION, Hsinchu (TW)

(21) Appl. No.: 10/891,143

(22) Filed: Jul. 15, 2004

(51) Int. Cl. H01L 29/788

(52) U.S. Cl. 257/315

(57) ABSTRACT

A split gate memory structure including two cells formed on a semiconductor substrate comprises a first conductive line, two dielectric spacers, two conductive spacers, two doping regions, a first dielectric layer and a second conductive line, where the two dielectric spacers, two conductive spacers and two doping regions are symmetrical along the first conductive line. The first conductive line is formed above the semiconductor substrate. The two dielectric spacers are formed beside the two sides of the first conductive line, respectively. The two conductive spacers, e.g., polysilicon spacers, are formed beside the two dielectric spacers, respectively. The two doping regions formed in the semiconductor substrate next to the two conductive spacers, respectively. The first dielectric layer is formed on the two conductive spacers and above the first conductive line. The second conductive line is formed on the first dielectric layer and perpendicular to the two doping regions.

### BACKGROUND OF THE INVENTION

(A) Field of the Invention

The present invention is related to a non-volatile memory structure and the manufacturing method thereof, and more particularly to a split gate memory structure and the manufacturing method thereof.

(B) Description of the Related Art

A conventional non-volatile memory cell normally needs high currents to operate, e.g., 200 microamperes (μA), for hot electron programming, so it is not suitable for low-power devices that are in the trend of chip development. Therefore, a split gate technology has been developed to obtain the high efficiency and low current programming, where the programming current can be diminished to, for example, 10 μA.

As shown in FIG. 1, U.S. Pat. No. 6,043,530 disclosed a flash EEPROM cell 114. A semiconductor substrate 100 of a first conductivity type, e.g., P-type, has a source region 105 and a drain region 108 of opposite conductivity type, e.g., N-type, formed therein. An active channel region 113 extends between the source region 105 and the drain region 108. A floating gate 103 is surmounted by a control gate 101 to form a stack gate with an oxide/nitride/oxide (ONO) layer 102 therebetween. Between the floating gate 103 and the substrate 100 is a tunnel oxide layer 104. Positioned above the channel region 113 and to the side of the stack gate 101, 103 is a polysilicon spacer 107 serving as an erase gate. A dielectric layer 106 between the control gate 101 and the erase gate 107 has to be thick enough to prevent any leakage current therebetween. A poly tunnel oxide layer 109, through which cell erase tunneling takes place, is formed between the floating gate 103 and the erase gate 107. An erase gate oxide 112 is formed between the erase gate 107 and the channel region 113. The floating gate 103 and the erase gate 107 are composed of polysilicon material while control gate 101 comprises polysilicon and tungsten silicide (WSi) materials to minimize the word line resistance. Accordingly, by minimizing the thickness of the poly tunnel oxide layer 109, a fast programming with low power consumption can be achieved, and cell size can be reduced.

As shown in FIG. 2, U.S. Pat. No. 6,242,774 disclosed a dual-gate cell structure with a self-aligned gate, with a view to minimizing the cell size. Such a dual-gate cell structure may be used in a split gate flash cell. A polysilicon spacer forms a second gate 213 separated from a first gate 201 made up of a polysilicon region 202 and a polycide region 204 by a dielectric layer 207, wherein the first gate 201 may operate as a select gate or control gate, whereas the second gate 213 may operate as a floating gate. A drain region 219 and a source region 221 are formed next to the gates 201 and 213 within a shallower well. The shallower well is positioned above a deep well region. In one embodiment, the second gate 213 acts as a floating gate in a flash cell. The floating gate may be programmed and erased by the application of appropriate voltage levels to the first gate 201, source 221, and/or drain 219. The self-aligned nature of the second gate 213 to the first gate 201 allows a very small dual-gate cell to be formed.

As shown in FIG. 3, U.S. Pat. No. 5,969,383 disclosed an EEPROM device including a split gate memory cell 310 having a source 336, a drain 322, a select gate 316 adjacent to the drain 322, and a control gate 332 adjacent to the source 336. When programming the split gate memory cell 310, electrons are accelerated in a portion of a channel region 338 between the select gate 316 and the control gate 332, and then injected into a nitride layer 324 of an ONO stack 325 underlying the control gate 332. The ONO stack 325 further comprises oxide layers 323 and 328. The split gate memory cell 310 is erased by injecting holes from the channel region 338 into the charged nitride layer 324. When reading data from the split gate memory cell 310, a reading voltage is applied to the drain 322 adjacent to the select gate 316. Data is then read from the split gate memory cell 310 by sensing a current flowing in a bit line coupled to the drain 322. Nitrides spacers 334 and 335 are formed along a sidewall 333 of the control gate 332 and on the ONO stack 325, respectively.

The spacers 107 and 213 of the cells illustrated in FIGS. 1 and 2 are formed at one side only, so that a further process to etch away the structure on the other side is needed. Moreover, the drain 322 and source 336 shown in FIG. 3 have to be implanted by two steps due to asymmetrical source 336 and drain 322. Consequently, these above known processes are more complex, and thus the cost is hard to be lowered.

### SUMMARY OF THE INVENTIION

The objective of the present invention is to provide a split gate memory structure for low power device applications, and the split gate memory structure is more easily manufactured, so the cost can be lowered effectively.

In order to achieve the above objective, a split gate memory structure including two cells formed on a semiconductor substrate is disclosed. The split gate memory structure comprises a first conductive line, two dielectric spacers, two conductive spacers, two doping regions, a first dielectric layer and a second conductive line, where the two dielectric spacers, two conductive spacers and two doping regions are symmetrical along the first conductive line. The first conductive line, e.g., a polysilicon line, is formed above the semiconductor substrate. The two dielectric spacers are formed beside the two sides of the first conductive line, respectively. The two conductive spacers, e.g., polysilicon spacers, are formed beside the two dielectric spacers, respectively. In other words, the dielectric spacers are disposed between the first conductive line and the conductive spacers for isolation. The two doping regions are formed in the semiconductor substrate next to the two conductive spacers, respectively, i.e., an edge of the doping region is aligned with a sidewall of the conductive spacer. The first dielectric layer, e.g., an ONO layer, is formed on the two conductive spacers and above the first conductive line. The second conductive line is formed on the first dielectric layer and is perpendicular to the two doping regions.

The first conductive line and conductive spacers function as a select gate and floating gates, respectively, whereas the doping regions and the second conductive line function as bit lines and a word line, respectively. In addition, the first conductive line may also serve as an erase gate for data erasure.

The above split gate memory structure can be manufactured by the following steps. First of all, a conductive line is formed above a semiconductor substrate, and then two dielectric spacers and two conductive spacers are sequentially formed beside the two sides of the conductive line, respectively. Second, dopants are implanted to form two doping regions in the semiconductor substrate next to the two conductive spacers, where an edge of the doping region is aligned with a sidewall of the conductive spacer. Afterwards, a first dielectric layer is formed on the two conductive spacers and above the first conductive line, followed by forming a second conductive line on the first dielectric layer, wherein the second conductive line is perpendicular to the doping regions.

### BRIEF DESCRIPTION OF THE DRAWINGS

FIGS. 1 through 3 illustrate known split gate memory cells;

FIGS. 4 through 8 illustrate the process of manufacturing the split gate memory structure in accordance with the present invention;

FIG. 9 illustrates the top view of the split gate memory structure in accordance with the present invention; and

FIG. 10 illustrates the schematic diagram with reference to the split gate memory structure in accordance with the present invention.

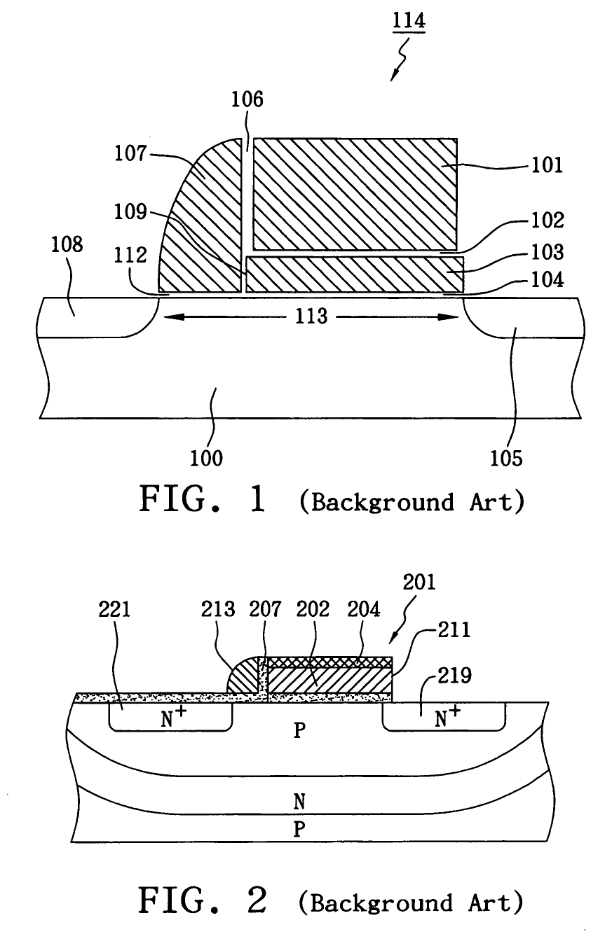

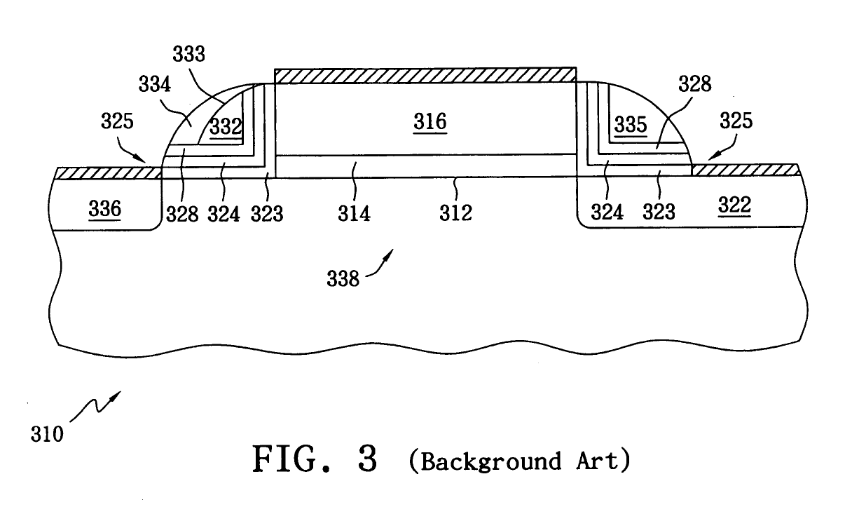

### DETAILED DESCRIPTION OF THE INVENTION

Embodiments of the present invention are now being described with reference to the accompanying drawings.

A process for making a split gate memory cell of NMOS type is exemplified as follows, with a view to illustrating the features of the present invention.

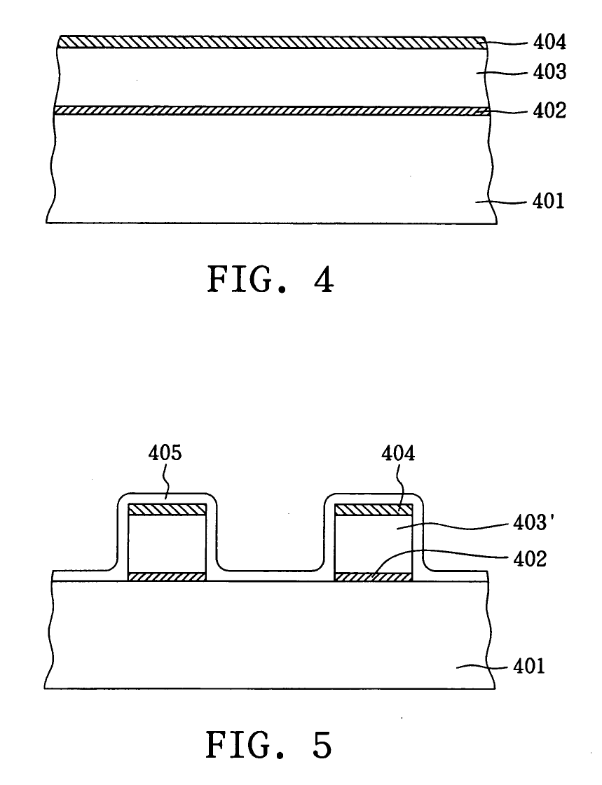

As shown in FIG. 4, a gate dielectric layer 402 ranging from 30 to 300 angstroms are thermally grown on the surface of a semiconductor substrate 401, and followed by sequentially depositing a first conductive layer 403 and a mask layer 404 thereon. The first conductive layer 403 may be composed of polysilicon and have a thickness between 500-2000 angstroms, and the mask layer 404 may be a silicon nitride layer of a thickness between 200-1000 angstroms.

In FIG. 5, the first conductive layer 403 and mask layer 404 are patterned by lithography and etching so as to form first conductive lines 403′ serving as select gates, and then a dielectric layer 405, for example, composed of oxide and ranging from 50-500 angstroms, is formed thereon.

In FIG. 6, an anisotropic etching is performed to form dielectric spacers 405′ ranging from 50-500 angstroms and followed by oxidization to form a dielectric layer 406 on channel regions. Then, a second conductive layer 407, for example, composed of polysilicon is deposited.

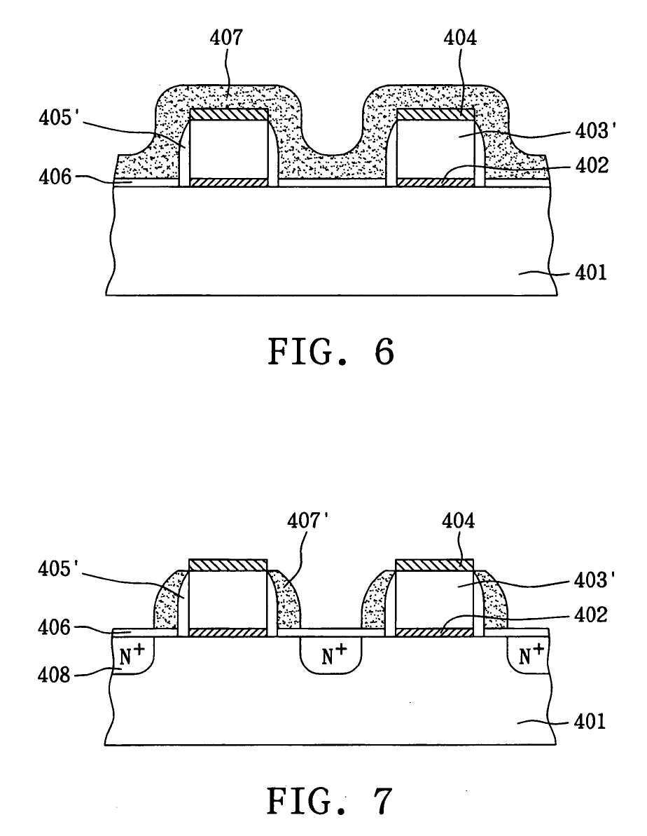

In FIG. 7, another anisotropic etching is performed so as to form conductive spacers 407′ beside the dielectric spacers 405′. The width of the conductive spacer 407′ is between 200 and 1000 angstroms, typically between 500 and 600 angstroms. The conductive spacers 407′ are used as floating gates for electron storage. Then, N⁺ dopants, e.g., arsenic ions, with 5×10¹⁴−5×10¹⁵ atoms/cm² are implanted to form doping regions 408 serving as bit lines in the semiconductor substrate 401, and the conductive spacers 407′ are also implanted at the same time. The edges of the doping regions 408 are aligned with the sidewalls of the conductive spacers 407′.

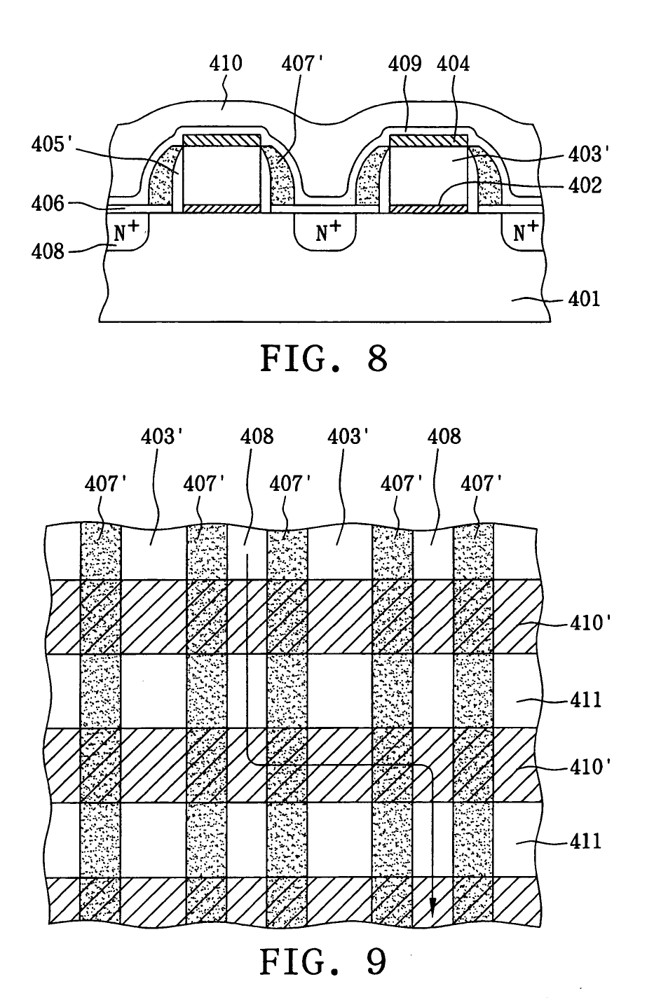

In FIG. 8, another dielectric layer 409 such as an oxide layer or an ONO layer ranging from 100 to 200 angstroms is formed along the contour of the device by either deposition or thermal growth, and then a third conductive layer 410, e.g., a polysilicon layer, is deposited thereon.

FIG. 9 illustrates the top view of the device shown in FIG. 8. Sequentially, the third conductive layer 410 is etched to form separated second conductive lines 410′ serving as word lines, and then CVD oxide is deposited and planarized to form isolating lines 411 therebetween. When a first conductive line 403′ is turned on, and the conductive spacers 407′ next to the first conductive line 403′ are also turned on by a second conductive line 410′, i.e., a word line, a current flowing through a doping region 408, i.e., a bit line, may flow as the arrow line shown in FIG. 9, i.e., flowing to the adjacent bit line.

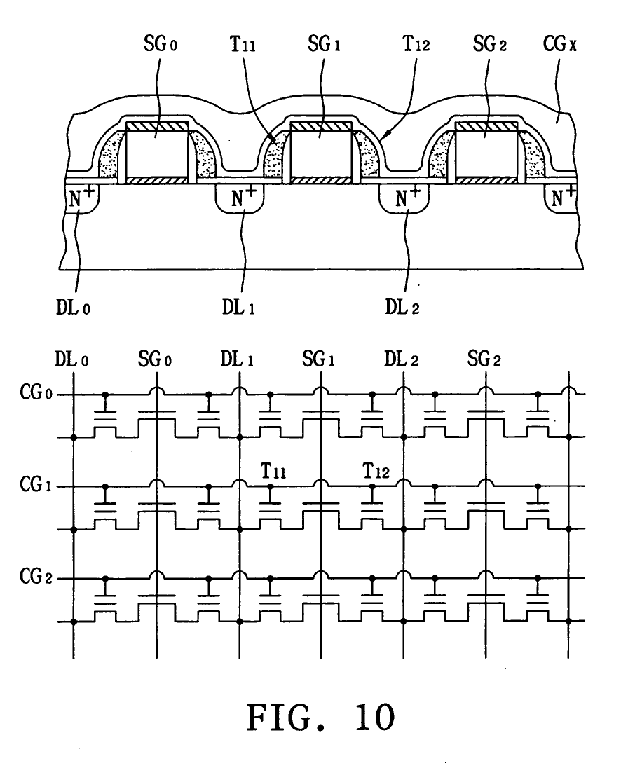

FIG. 10 illustrates a schematic diagram with reference to the split gate memory structure put forth in the present invention, in which the memory cell architecture is the same as that shown in FIG. 8 but some components are renamed by their functionality, where a data line (bit line), is denoted by DL, a select gate is denoted by SG, and a control gate (word line), is denoted by CG. Storage memory cell is denoted by T, where T₁₁ and T₁₂ is the cells at both sides of a select gate SG₁. Examples for reading, programming and erasing of memory cells T₁₁ and T₁₂ are shown in Table 1. For instance, for programming T₁₁, the DL₁ and DL₂ are 5V and 0V respectively, CG₁ is 12V, and SG₁ is 1.5V. Accordingly, T₁₁ and T₁₂ are turned on by the voltage of CG₁ coupling to the T₁₁ and T₁₂, and the SG₁ is turned on also. Consequently, 5V and 0V are at the left side and right side of the dielectric spacer 405′ beside the left side of the SG₁, respectively, i.e, 5V bias is generated across the dielectric spacer 405′. Therefore, electrons will be jumped into the storage cell of T₁₁ for programming. For reading T₁₁, in addition to that CG₁ and SG₁ are 5V and 3-5V respectively, the DL₂ of 1.5V is intended to deplete the doping region 408, so as to ignore the effect of T₁₂, i.e., no matter whether the T₁₂ is programmed or not. Accordingly, no current occurs if the T₁₁ is programmed, and, in contrast, current occurs if the T₁₁ is not programmed. For erasing T₁₁, a high negative voltage such as −18V is applied to the CG₁ to expel electrons out of the conductive spacer 407′ into the semiconductor substrate 401 through the dielectric layer 406 underneath.

TABLE 1

| | | CG₀ | CG₁ | | CG₂ | SG₀ | SG₁ | | SG₂ | DL₀ | DL₁ | DL₂ |
|---|---|---|---|---|---|---|---|---|---|---|---|---|
| T₁₁ | Program | 0 V | 12 | V | 0 V | 0 V | 1.5 | V | 0 V | 0 V | 5 V | 0 V |
| | Read | 0 V | 5 | V | 0 V | 0 V | 3-5 | V | 0 V | 0 V | 0 V | 1.5 V |
| | Erase | 0 V | −18 | V | 0 V | 0 V | 0 | V | 0 V | 0 V | 0 V | 0 V |
| T₁₂ | Program | 0 V | 12 | V | 0 V | 0 V | 1.5 | V | 0 V | 0 V | 0 V | 5 V |
| | Read | 0 V | 5 | V | 0 V | 0 V | 3-5 | V | 0 V | 0 V | 1.5 V | 0 V |
| | Erase | 0 V | −18 | V | 0 V | 0 V | 0 | V | 0 V | 0 V | 0 V | 0 V |

Further, the dielectric spacer 407′ may function as a tunnel oxide also, and the first conductive line 403′ may function as an erase gate. Consequently, the erase conditions are listed in Erase (I) of Table 2. If oxide damage owing to high voltage such as 10V used in Erase (I) is a concern, a manner by partitioning voltage can be employed as shown in Erase (II). For instance, the SG₁ is 6V, and CG₁ is −8V, and therefore approximately −4V will be coupled to the SG₁ in the case of 50% coupling ratio. Therefore, 10V bias is generated, which is substantially equivalent to that shown in the Erase (I).

TABLE 2

| | | CG₀ | CG₁ | CG₂ | SG₀ | SG₁ | SG₂ | DL₀ | DL₁ | DL₂ |
|---|---|---|---|---|---|---|---|---|---|---|
| T₁₁ | Erase (I) | 0 V | 0 V | 0 V | 0 V | 10 V | 0 V | 0 V | 0 V | 0 V |
| | Erase (II) | 0 V | −8 V | 0 V | 0 V | 6 V | 0 V | 0 V | 0 V | 0 V |

Accordingly, the split gate memory cells made in accordance with the present invention is a symmetrical structure and can be well operated by sophisticated voltage control manner, so no further etching or implantation process is needed. Therefore, the manufacturing process can be simplified, and thus the cost can be reduced.

Besides the manufacturing method regarding NMOS type transistor mentioned above, the PMOS type transistor can also be implemented by doping boron ions without departing from the spirit of the present invention.

The above-described embodiments of the present invention are intended to be illustrative only. Numerous alternative embodiments may be devised by those skilled in the art without departing from the scope of the following claims.

1. A split gate memory structure including two cells formed on a semiconductor substrate, comprising:
a first conductive line formed above the semiconductor substrate;
two dielectric spacers formed beside the two sides of the first conductive line, respectively;
two conductive spacers formed beside the two dielectric spacers, respectively; two doping regions formed in the semiconductor substrate next to the two conductive spacers, respectively;
a first dielectric layer formed on the two conductive spacers and above the first conductive line; and
a second conductive line formed on the first dielectric layer and being perpendicular to the two doping regions.

2. The split gate memory structure in accordance with claim 1, wherein the first conductive line and conductive spacers serve as a select gate and floating gates, respectively.

3. The split gate memory structure in accordance with claim 1, wherein the doping regions and second conductive line serve as bit lines and a word line, respectively.

4. The split gate memory structure in accordance with claim 1, further comprising a second dielectric layer between the conductive spacer and the semiconductor substrate.

5. The split gate memory structure in accordance with claim 4, wherein the second dielectric layer serves as a tunnel oxide layer.

6. The split gate memory structure in accordance with claim 1, wherein the first conductive line serves as an erase gate, and the dielectric spacers serve as tunnel oxide layers.

7. The split gate memory structure in accordance with claim 1, wherein an edge of the doping region is aligned with a sidewall of the conductive spacer.

8. The split gate memory structure in accordance with claim 1, further comprising a mask layer on the first conductive line.

9. The split gate memory structure in accordance with claim 1, wherein the first dielectric layer is an oxide/nitride/oxide layer.

10. The split gate memory structure in accordance with claim 1, wherein the first conductive line is composed of polysilicon.

11. The split gate memory structure in accordance with claim 1, wherein the dielectric spacer is of a thickness between 50-500 angstroms.

12. The split gate memory structure in accordance with claim 1, wherein the width of the conductive spacer is between 200 to 1000 angstroms.

13. The split gate memory structure in accordance with claim 1, wherein the two dielectric spacers, two conductive spacers and two doping regions are symmetrical along the first conductive line.

14. The split gate memory structure in accordance with claim 1, wherein the conductive spacer is programmed by generating a bias voltage across the dielectric spacer.

15. The split gate memory structure in accordance with claim 14, wherein the bias voltage is generated by turning on the first conductive line and the two conductive spacers and applying different voltages to the two doping regions.

16. The split gate memory structure in accordance with claim 1, wherein reading the programmed status of one of the conductive spacers comprising the step of putting a bias voltage on the doping region next to the other conductive spacer such that the depletion region across the other conductive spacer, so as to ignore the effect of the other conductive spacer if being programmed.

17. A method for manufacturing a split gate memory structure including two cells, comprising the steps of:
providing a semiconductor substrate;
forming a first conductive line above the semiconductor substrate;
forming two dielectric spacers beside both sides of the first conductive line, respectively;
forming two conductive spacers beside the two dielectric spacers respectively; implanting dopants to form two doping regions in the semiconductor substrate next to the two conductive spacers, respectively;
forming a first dielectric layer on the two conductive spacers and above the first conductive line; and
forming a second conductive line on the first dielectric layer, wherein the second conductive line is perpendicular to the doping regions;
wherein the two conductive spacers are implanted at the time of implanting the two doping regions.

18. The method for manufacturing a split gate memory structure in accordance with claim 17, wherein the two dielectric spacers, two conductive spacers and two doping regions are symmetrical along the first conductive line.

19. The method for manufacturing a split gate memory structure in accordance with claim 17, further comprising the step of forming a second dielectric layer between the semiconductor substrate and the first conductive line.

20. The method for manufacturing a split gate memory structure in accordance with claim 17, further comprising the step of forming a third dielectric layer on the semiconductor substrate between two adjacent conductive spacers.

21. (canceled)

22. The method for manufacturing a split gate memory structure in accordance with claim 17, wherein an edge of the doping region is aligned with a sidewall of the conductive spacer.
